(19) United States
(12) Patent Application Publication
(10) Pub. No.: US 2018/0202835 A1
(43) Pub. Date: Jul. 19, 2018

(54) SENSOR FOR MEASURING THE ABSOLUTE POSITION OF A MOVING PART

(71) Applicant: ELECTRICFIL AUTOMOTIVE, Miribel Cedex (FR)

(72) Inventors: Rainer MÖLLER, Chaponnay (FR); Mathieu LE NY, Villeubanne (FR)

(73) Assignee: ELECTRICFIL AUTOMOTIVE, Miribel Cedex (FR)

(21) Appl. No.: 15/742,607

(22) PCT Filed: Jul. 13, 2016
(86) PCT No.: PCT/FR2016/051810

§ 371 Date: Jan. 8, 2018

(30) Foreign Application Priority Data
Jul. 21, 2015 (FR) 15 56911

(51) Int. Cl. G01D 5/14; G01D 5/245; G01B 7/00; G01R 33/06

(52) U.S. Cl. CPC G01D 5/145; G01R 33/06; G01B 7/003; G01D 5/2452

(57) ABSTRACT

The invention provides a measurement sensor for determining the position of a moving body, the sensor comprising a series of at least four detector probes for detecting a physical magnitude coming from a target comprising at least one track for creating a physical magnitude that is measurable by the detector probes and that varies along the path of the target with a function that is continuous and that includes a first harmonic and a second harmonic, the probes being connected to a processor unit for processing signals delivered by the probes, the processor unit including a reconstruction system for performing a linear combination of the signals and for obtaining firstly two quadrature signals including solely the first harmonic, and secondly two quadrature signals including solely the second harmonic, the unit also including a calculation system for processing the quadrature signals in order to determine the position of the moving body.

The present invention relates to the technical field of measurement sensors for determining the absolute position of a moving body that moves on a path that is circular, linear, or curvilinear.

The subject matter of the invention presents numerous applications and in particular in the automotive field, e.g. for accurately measuring the angular position of a camshaft or of a crankshaft or the linear position of a selector lever of an automatic gearbox.

The state of the art has proposed numerous technical solutions for determining the absolute position of a moving body.

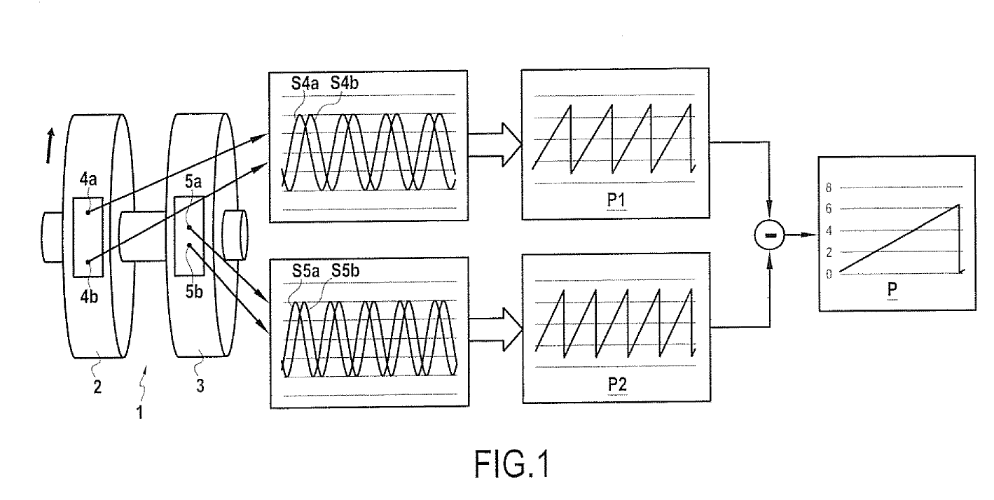

For example, patent application WO 01142753 describes a measurement sensor having a series of detector probes for detecting a physical magnitude coming from two targets mounted securely on the moving body 1 of position that is to be measured. Typically, and as shown in FIG. 1, the physical magnitude to be measured is a magnetic field provided by two magnetic targets 2 and 3, one of which presents a number of magnetic poles that is different from the number of magnetic poles of the other track. Each target 2, 3 is made so that the magnetic field measured by the detector probes vary sinuosoidally along the travel path with periodicity that differs between the two targets. Two measurement probes 4a, 4b and 5a, 5b are placed respectively facing each of the targets 2, 3, being mutually offset along the travel path so as to generate, for each target, two sinusoidal signals S4a, S4b and S5a, S5b that are mutually phase-shifted by one-fourth of a period. Such sinusoidal signals are subjected to trigonometric processing that serves to determine the relative position P1, P2 for each target of the moving body within one period. The difference between the relative positions P1, P2 of the moving body, as obtained for each target, makes it possible to determine the absolute position P of the moving body. That measurement method is known as the “vernier” method or as the “modified vernier” method.

Such a measurement method is also described in patent application WO 2014/131434.

The measurement sensor described in that patent application requires the use of two targets and two detectors, each having two measurement probes that are spaced apart by a value equal to the wavelength divided by four. Insofar as the wavelengths are different for the two tracks, such a sensor requires a detector that is specific for each target. Furthermore, the distance between the two targets must be great enough to limit cross-talk. In addition to the problem of cost, such a measurement sensor raises a problem of size that can be found to be prohibitive in applications for which the space available for mounting the measurement sensor is very small.

Patent application EP 2 385 353 describes a measurement sensor having a magnetic track constituted by magnetic poles of width that is modulated in such a manner as to obtain a signal comprising a high frequency component corresponding to the periodicity of pairs of poles and a low frequency component corresponding to one period per mechanical revolution of the target. Such a magnetic signal is detected by two measurement probes arranged close to each other. The sum and the difference of the signals delivered by those probes are calculated in order to determine the position of the moving body.

It should be observed that, with a small air gap, the magnetic signal generated by such a magnetic track contains a large amount of harmonic distortion (at a multiple of the period of the pairs of poles) having the consequence of degrading the accuracy of the measurement. With a large airgap, the harmonic distortion is smaller but the amplitude of the magnetic signal is weaker, which also leads to degrading the accuracy of the measurement. Furthermore, the differential signal still contains a non-negligible fraction of the modulation signal, which also degrades the accuracy of the measurement. Finally, the signals with those two measurement probes do not make it possible to determine the absolute position unambiguously when the moving body has stopped. In order to remedy that problem, that document proposes adding a third measurement probe positioned at 90° relative to the other two. In addition to a problem of cost, that solution raises the problem of size.

A measurement sensor is also known from patent application US 2008/024122 for determining the position of a moving body that moves along a determined path. That sensor has at least four detector probes for detecting a physical magnitude coming from a target mounted securely on the moving body. The target emits a pseudo-sinusoidal signal that varies as a function of the position of the target. Such a sensor has means for linearly combining signals delivered by the probes so as to form two pseudo-sinusoidal signals that are in quadrature and of the same amplitude. Such a sensor does not make it possible to measure the absolute position of a moving body with great accuracy.

The subject matter of the present invention seeks to remedy the drawbacks of prior solutions by proposing a sensor that enables the absolute position of a moving body to be measured with great accuracy and that is adapted to be capable of being installed in a limited volume while presenting small cost.

In order to achieve this object, the measurement sensor of the invention seeks to measure the position of a moving body moving along a determined path, the sensor comprising a series of at least four detector probes for detecting a physical magnitude coming from a target securely mounted on the moving body, the target comprising at least one track for creating a physical magnitude that is measurable by the detector probes and that varies along the path of the target with a function that is continuous and that includes a first harmonic and a second harmonic, the probes being connected to a processor unit for processing signals delivered by the probes, the processor unit including a reconstruction system for performing a linear combination of the signals delivered by the detector probes and for obtaining from the liner combination of those signals at least firstly two quadrature signals including solely the first harmonic, and secondly two quadrature signals including solely the second harmonic, the unit also including a calculation system for processing the quadrature signals in order to determine the position of the moving body.

Furthermore, the sensor of the invention may also present in combination at least one and/or another of the following additional characteristics:
the calculation system for determining the position of the moving body calculates the A tan 2 of the two quadrature signals including the first harmonic and the A tan 2 of the two quadrature signals including the second harmonic, the calculation system giving two relative positions for the moving body;
the calculation system calculates the difference between the two relative positions for the moving body modulo 2ϕ in order to obtain the absolute position of the moving body;
the first harmonic and the second harmonic present respectively a first spatial frequency and a second spatial frequency such that the ratio of the spatial frequencies is given by the following relationship;

Nₐ=αN_{c}±1

where α is an integer greater than 1;
the target creates a magnetic field that varies continuously and that includes the first and second harmonics, the amplitude or the direction of the magnetic field being detected by the detector probes;
the reconstruction system performs a linear combination of the signals delivered by the probes by applying weighting weights, these weighting weights being programmable in such a manner as to enable the quadrature signals to be reconstructed for a spacing of given value between the probes;
the weighting weights of the reconstruction system are selected so as to obtain a zero contribution from the uniform component of the magnetic field to the reconstructed signals;
the maximum distance between two of its detector probes is strictly less than one half-period of the first spatial frequency;
all of the detector probes are grouped together in a single microelectronic integrated circuit;
at least two probes located on the path of the target enable the component of the magnetic field that is tangential to the path to be measured, and at least two probes located along the path of the target enable a component of the magnetic field that is perpendicular to the path to be measured; and
the target has two tracks, each track being magnetized with one of the two harmonics, and the detector probes are positioned substantially centered relative to the two tracks.

Various other characteristics appear from the following description given with reference to the accompanying drawings which show embodiments of the invention as non-limiting examples.

FIG. 1 shows a sensor of the prior art.

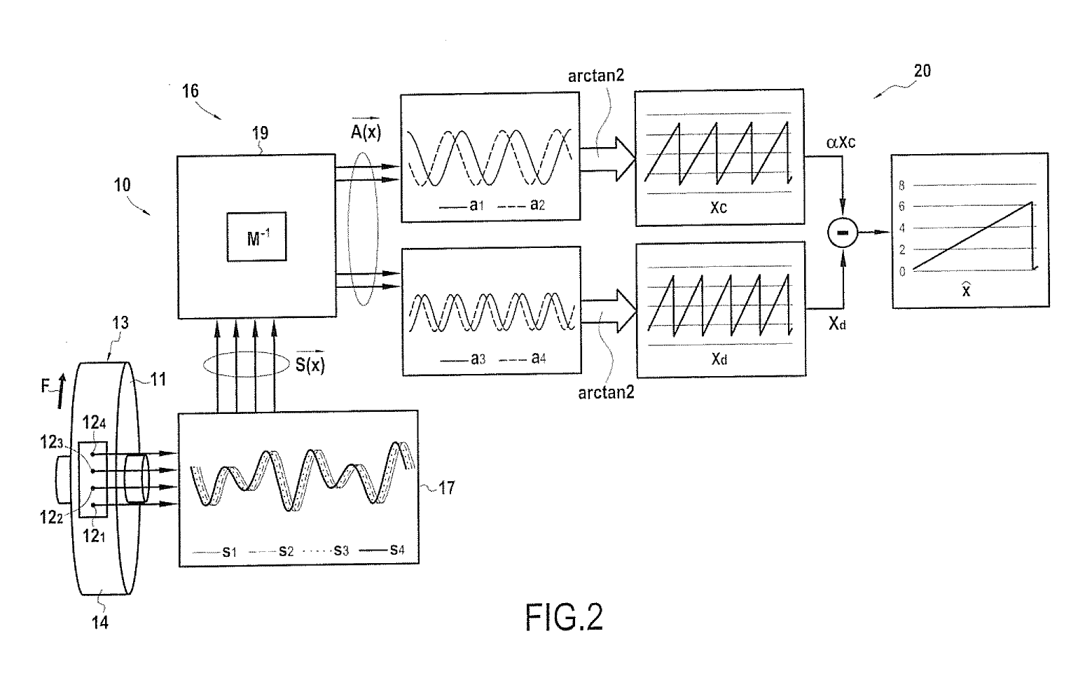

FIG. 2 is a functional representation of an embodiment of an angular position sensor of the invention.

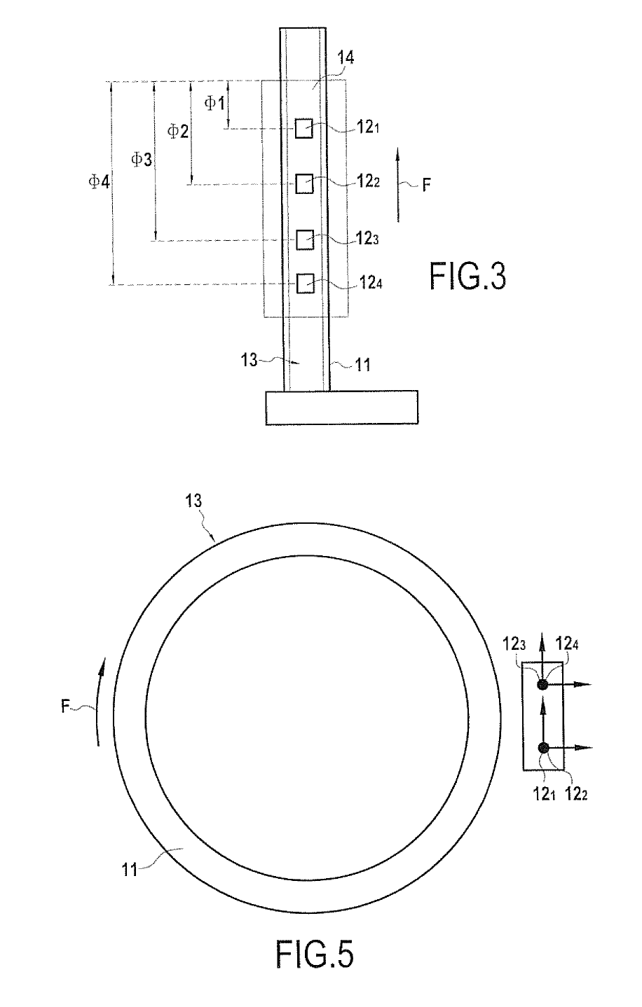

FIG. 3 is a diagram showing a linear position sensor of the invention.

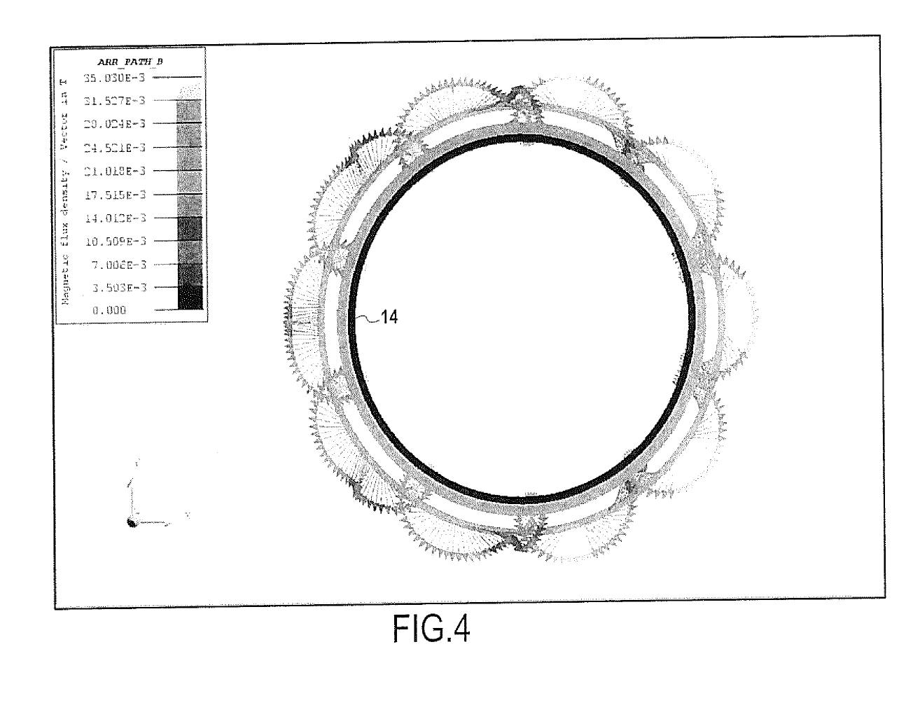

FIG. 4 shows an embodiment of a magnetized target for an angular sensor of the invention.

FIG. 5 shows an angular position sensor of the invention with probes measuring two orthogonal components of the magnetic field generated by the magnetized target.

As can be seen more precisely in FIG. 2, the invention relates to a measurement sensor 10 for determining the position of a moving body 11 moving along a determined path that is represented by arrow F. In the example shown in FIG. 2, the moving body 11 moves along a circular path such that the sensor is an angular position sensor. In the example shown in FIG. 3, the moving body 11 moves along a rectilinear path so that the sensor is a linear position sensor. Naturally, the measurement sensor of the invention is suitable for determining the position of a moving body that follows some other path, such as a curvilinear path.

The sensor 10 of the invention has a series of at least four detector probes 12₁, 12₂, 12₃, 12₄, . . . , 12_{N} for detecting a physical magnitude coming from a target 13 mounted securely to the moving body 11. The target 13 has one or more tracks 14 for creating a physical magnitude that is measurable by the detector probes. This measurable physical magnitude varies along the path of the moving body with a function that is continuous and it has a first harmonic N_{c} and a second harmonic N_{d}. In a preferred embodiment, the measurable physical magnitude is a magnetic field such that the sensor has a magnetized target and Hall effect probes. Naturally, the measurable physical magnitude may be of some other kind. Thus, the target 13 may have conductive tracks of varying width and the probes may be coils powered at high frequency so as to be capable of measuring variation of inductances as a function of the width of the track facing the coil as a result of eddy currents. In order to simplify the description, the detailed description below describes the embodiment having a magnetized target and Hall effect probes.

In the example under consideration, the target 13 has a magnetized track 14. The amplitude or the direction of the magnetization of the track varies in the travel direction of the target with a function that is continuous and that includes a first harmonic N_{c} and a second harmonic N_{d}.

The detector probes 12₁, 12₂, 12₃, 12₄, . . . , 12_{N} are connected to a processor unit for processing signals s₁, s₂, s₃, s₄, . . . s_{N} delivered by the probes.

As described in greater detail in the description below, the processor unit 16 has a system 17 for acquiring and processing signals delivered by the detector probes, and connected to a reconstruction system 19 for performing a linear combination of the signals delivered by the probes. The reconstruction system 19 serves to perform a linear combination of the signals s₁, s₂, s₃, s₄, . . . , s_{N} to obtain at least firstly two quadrature signals a₁, a₂ including solely the first harmonic N_{c}, and secondly two quadrature signals a₃, a₄ containing solely the second harmonic N_{d}. The processor unit 16 also has a calculation system 20 for processing the quadrature signals in order to determine the position of the moving body. Typically, the calculation system 20 gives two relative positions X_{c} and X_{d} for the moving body 11 by calculating the two-argument inverse tangent (A tan 2) of the two quadrature signals having the first harmonic N_{c} (i.e. the signals a₁ and a₂ in the example shown) and the A tan 2 of the two quadrature signals having the second harmonic N_{d} (i.e. the signals a₃ and a₄ in the example shown). The calculation system 20 then takes the difference modulo 2n between the two relative positions X_{c} and X_{d} for the moving body in order to obtain the absolute position x of the moving body.

The description below describes in greater detail the unit 16 for processing the signals s₁, s₂, s₃, s₄, . . . , s_{N} delivered by the probes. It should be considered that the detector probes 12₁, 12₂, 12₃, 12₄, . . . , 12_{N} are mutually offset in the travel direction of the target. The magnetic field b measured at a point x in a given direction may be described as follows:

b(x)=V_{c} cos(w_{c}x)+V_{d} cos(w_{d}x)

where w_{c}=2πN_{c}/L and w_{d}=2πN_{d}/L, where N_{c} and N_{d} are integer numbers corresponding to the number of periods of each harmonic over the stroke L of the target 11, and where x is the position taken along the path. The first harmonic thus presents a first spatial frequency N_{c} (e.g. considered to be low frequency) and the second harmonic presents a second spatial frequency N_{d} (e.g. considered to be a high frequency). The parameters V_{c} and V_{d} correspond to the amplitudes of these two harmonics.

Typically, the sensor 1 of the invention uses the acquisition and processor system 17 to take N simultaneous measurements sₖ of the magnetic field generated by the magnetized track 14. In the example shown in FIGS. 2 and 3, these measurements are taken using the probes 12₁ to 12₄ (N=4 in this example), which probes are mutually offset in the travel direction F. These various measurements sₖ are defined by:

sₖ(x)=b(x+ϕₖ)

where ϕₖ corresponds to the position of each measurement, i.e. to the positions selected for the detector probes 12₁ to 12₄ (FIG. 3). By means of conventional trigonometric formulae, sₖ may be rewritten as follows:

sₖ(x)=V_{c} cos(w_{c}ϕₖ)·cos(w_{c}x)−V_{c} sin(w_{c}ϕₖ)·sin(w_{c}x)+V_{d} cos(w_{d}ϕₖ)·cos(w_{d}x)−V_{d} sin(w_{d}ϕₖ)·sin(w_{d}x)

It is possible to rewrite this formula in the following matrix format:

$$( \begin{matrix}{s}_{1} ( x ) \\ ⋮ \\ {s}_{N} ( x )\end{matrix} ) = ( \begin{matrix}{V}_{c} cos ( {w}_{c} {φ}_{1} ) & - {V}_{c} sin ( {w}_{c} {φ}_{1} ) & {V}_{d} cos ( {w}_{d} {φ}_{1} ) & - {V}_{d} sin ( {w}_{d} {φ}_{1} ) \\ ⋮ & ⋮ & ⋮ & ⋮ \\ {V}_{c} cos ( {w}_{c} {φ}_{N} ) & - {V}_{c} sin ( {w}_{c} {φ}_{N} ) & {V}_{d} cos ( {w}_{d} {φ}_{N} ) & - {V}_{d} sin ( {w}_{d} {φ}_{N} )\end{matrix} ) ( \begin{matrix}{a}_{1} ( x ) \\ {a}_{2} ( x ) \\ {a}_{3} ( x ) \\ {a}_{4} ( x )\end{matrix} )$$

where the new variables a_{P} are given by:

$$\{ \begin{matrix}{a}_{1} ( x ) = cos ( {w}_{c} x ) \\ {a}_{2} ( x ) = sin ( {w}_{c} x ) \\ {a}_{3} ( x ) = cos ( {w}_{d} x ) \\ {a}_{4} ( x ) = sin ( {w}_{d} x )\end{matrix}$$

This formula can be written more simply using matrix notation:

S(x)=·A(x)

where S corresponds to the N×1 column vector containing all of the measurements sₖ depending on the position x, and where M is an N×4 matrix depending on the position ϕₖ and on the periodicities w_{c} and w_{d} or spatial frequencies N_{c} and N_{d}. Finally, A is a 4×1 vector containing the variables aₚ depending on the position x in simpler manner than the variables sₖ. Since the relationships between the position x and the variables aₚ are simpler, the purpose is thus to determine these values aₚ from the various measurements sₖ. With N=4 different measurements, and if the matrix M is a full rank matrix, the new variables aₚ can be determined as follows as a function of the measurements sₖ:

A(x)=M⁻¹·S(x)

where M⁻¹ is the matrix that is the inverse of the above-described matrix M, and is also referred to as the weighting matrix.

It should be observed that the weighting matrix M⁻¹, like the matrix M, depends solely on constant and known parameters of the measurement system, i.e. on the position ϕₖ of the detector probes and on the periodicities w_{c} and w_{d}. For a given measurement system, it is thus possible to determine a matrix M⁻¹ that transforms the vector S(x) of N measurements, each comprising both harmonics, into a vector A(x) of four signals a₁, a₂, a₃, a₄ in the example shown.

This matrix M⁻¹ defines the weighting weights that are applied to the signals s₁, s₂, s₃, s₄ by the reconstruction system 19 in order to obtain the signals a₁, a₂, a₃, a₄. The four signals of the vector A(x) comprise firstly two quadrature signals a₁, a₂ including solely the first harmonic N_{c}, and secondly two quadrature signals a₃, a₄ including solely the second harmonic N_{d}.

In other words, the reconstruction system 19 performs a linear combination of the signals delivered by the probes by applying weighting weights selected as a function firstly of the spatial frequencies of the two harmonics and secondly of the distances between the detector probes.

These weighting weights are preferably programmable so as to enable the quadrature signals to be reconstructed for a spacing of given value between the probes and for different spatial frequencies. Thus, a standard subassembly comprising probes 12₁, 12₂, 12₃, 12₄, . . . , 12_{N} with constant spacing between the probes can be used for several variant sensors with targets having a variety of diameters and spatial frequencies.

In the general situation where the number of measurements N is greater than 4, the vector A(x) can always be determined by the method of least squares:

A(x)=(M^{T}M)⁻¹M^{T}·S(x)

where M^{T} is the transpose of the matrix M.

Once the vector A has been determined, the calculation system 20 can determine the position x very easily. Initially, two relative positions X_{c} and X_{d} are calculated:

$$\{ \begin{matrix}{X}_{c} ( x ) = a tan 2 ( {a}_{2} ( x ) , {a}_{1} ( x ) ) = modulo ( x , \frac{L}{{N}_{c}} ) \\ {X}_{d} ( x ) = a tan 2 ( {a}_{4} ( x ) , {a}_{3} ( x ) ) = modulo ( x , \frac{L}{{N}_{d}} )\end{matrix}$$

where the function a tan 2 is the function linking the sine and cosine functions to the angle over a period of 2π.

Finally, the absolute position x of the target 13 may be estimated as follows:

\hat{x}=modulo(X_{c}−X_{d},2π)

It is possible to improve the sensor so that it cancels out an external magnetic field that is uniform. For this purpose, assume that the total field b(x) is now written as follows:

b(x)=V_{c} cos(w_{c}x)+Vₐ cos(w_{d}x)+Vₑ

where Vₑ is the amplitude of the uniform external magnetic field. The measurements sₖ are now written as follows:

$$( \begin{matrix}{s}_{1} ( x ) \\ ⋮ \\ {s}_{N} ( x )\end{matrix} ) = ( \begin{matrix}{V}_{c} cos ( {w}_{c} {φ}_{1} ) & - {V}_{c} sin ( {w}_{c} {φ}_{1} ) & {V}_{d} cos ( {w}_{d} {φ}_{1} ) & - {V}_{d} sin ( {w}_{d} {φ}_{1} ) & 1 \\ ⋮ & ⋮ & ⋮ & ⋮ & ⋮ \\ {V}_{c} cos ( {w}_{c} {φ}_{N} ) & - {V}_{c} sin ( {w}_{c} {φ}_{N} ) & {V}_{d} cos ( {w}_{d} {φ}_{N} ) & - V sin ( {w}_{d} {φ}_{N} ) & 1\end{matrix} ) ( \begin{matrix}{a}_{1} ( x ) \\ {a}_{2} ( x ) \\ {a}_{3} ( x ) \\ {a}_{4} ( x ) \\ {V}_{e}\end{matrix} )$$

The matrix M now possesses an additional column. Consequently, it suffices to perform N=5 distinct measurements so that the matrix is once more square and invertible. Thus, it is possible to determine separately the contributions of the useful variables a_{P} and of the external magnetic noise Vₑ. In this variant embodiment, the reconstruction system 19 uses the linear combination of the weighted signals to obtain firstly two quadrature signals a₁, a₂ including solely the first harmonic, and secondly two quadrature signals a₃, a₄ containing solely the second harmonic, together with the signal Vₑ including solely the uniform component of the magnetic field. The weighting weights of this reconstruction system 19 make it possible to obtain a contribution of zero from the uniform component of the magnetic field to the reconstructed signals a₁, a₂, a₃, a₄.

So long as the entire processing system remains under linear conditions, the signals a₁, a₂, a₃, a₄ are not influenced by the uniform magnetic field, and consequently the position measurement is not disturbed by a uniform external magnetic field. In certain applications, the external magnetic field may reach extreme values that cause the magnetic probes to saturate or that cause a portion of the processing system to saturate, which can lead to an erroneous measurement. In applications that require a high level of operating safety, it can therefore be useful to validate the determined position only when the signal Vₑ representing the external magnetic field remains within acceptable limits, and to issue an alert signal otherwise.

The weighting matrix M⁻¹ is determined so as to completely eliminate the unwanted harmonics in the signals a₁(x) to a_{N}(x). It is possible that this weighting matrix simultaneously gives rise to large attenuation of the useful harmonic, which would have the consequence of degrading the signal-to-noise ratio and thus the accuracy of the measurement. This unwanted attenuation depends on the spacing between the measurement points and on the spatial frequencies used. In general manner, for a given spacing of measurement points, a weighting matrix that enables one given spatial frequency to be cancelled completely is likely to greatly attenuate spatial frequencies that are nearby. The conventional vernier method makes use of two frequencies associated by the equation:

N_{d}=N_{c}±1

In order to obtain good measurement resolution, it is desirable to select numbers N_{c} and N_{d} that are high, and under such circumstances it can be considered that the frequencies are close together and that the attenuation of the useful signal runs the risk of being considerable. In order to remedy this problem, it is proposed in a preferred version of the invention to use a relationship between the two spatial frequencies N_{c}, N_{d} in compliance with the following equation:

N_{d}=αN_{c}±1

where α is an integer greater than 1.

This makes it possible to obtain a greater difference between the spatial frequencies used, while maintaining the possibility of finding the absolute position. The absolute position x is then obtained from two relative positions X_{c} and X_{d} by using the following equation:

\hat{x}=modulo(αX_{c}−X_{d},2π)

According to an advantageous embodiment characteristic, the maximum distance between two detector probes 12₁, 12₂, 12₃, 12₄, . . . , 12_{N} is strictly less than one half-period of the first spatial frequency N_{c}, i.e. the lower frequency.

According to another advantageous embodiment characteristic, all of the detector probes 12₁, 12₂, 12₃, 12₄, . . . , 12_{N} are grouped together in a single microelectronic integrated circuit 22. Such an advantage is made possible by the fact that all of the detector probes can be mounted close to one another. Typically, all of the detector probes can be accommodated on an area of the order of a few square millimeters (mm²).

In the examples shown in FIGS. 2 and 3, the target 13 has a single track 14 for creating a physical magnitude that is measurable by the detector probes and that varies along the path of the target with a continuous function including a first harmonic N_{c} and a second harmonic N_{d}. FIG. 4 shows an embodiment of a magnetized target 14 having a single magnetized track. The arrows represent the direction of the magnetic flux and the gray shades represent its intensity. Making the target with a single track contributes to making a measurement sensor that is compact.

It should be observed that the measurement sensor of the invention may be used with a target 13 having two tracks 14 mounted side by side, each being magnetized with a respective one of the two harmonics. In a preferred embodiment variant, the two tracks 14 are arranged to be side by side while the detector probes 12₁, 12₂, 12₃, 12₄, . . . , 12_{N} are positioned to be substantially centered relative to the two side-by-side tracks. In other words, the detector probes 12₁, 12₂, 12₃, 12₄, . . . , 12_{N} are placed over the junction between the two tracks.

FIG. 5 shows another sensor in a variant of the invention. In this variant, instead of using four probes distributed over four positions that are shifted in the measurement direction, two pairs of probes 12₁, 12₂ and 12₃, 12₄ are used that are located at only two different positions in the travel direction, each pair of probes measuring two components of the magnetic field in two perpendicular directions, comprising a component b_{T} that is tangential to the path and a component b_{P} that is perpendicular to the path. Firstly, the magnetic field around the target may be approximated in the same manner as above in two directions in three-dimensional space:

b_{P}(x)=V_{Pc} cos(w_{c}x)+V_{Pd} cos(w_{d}x)

b_{T}(x)=V_{Tc} sin(w_{c}x)+V_{Td} sin(w_{d}x)

where b_{P} and b_{T} are two mutually perpendicular components of the magnetic field, and where the coefficients Vₓₓ are constants which can be obtained by simulation or by measurement. In this variant of the invention, the four measurements sₖ are defined as follows:

s₁(x)=b_{P}(x+ϕ₁)

s₂(x)=b_{P}(x+ϕ₂)

s₃(x)=b_{T}(x+ϕ₁)

s₄(x)=b_{T}(x+ϕ₂)

where ϕ₁ and ϕ₂ are the two measurement positions in this variant of the invention. By using conventional trigonometric formulae, it is possible as above to write a matrix system:

$$( \begin{matrix}{s}_{1} ( x ) \\ {s}_{2} ( x ) \\ {s}_{3} ( x ) \\ {s}_{4} ( x )\end{matrix} ) = ( \begin{matrix}{V}_{Pc} cos ( {w}_{c} {φ}_{1} ) - {V}_{Pc} sin ( {w}_{c} {φ}_{1} ) {V}_{Pd} cos ( {w}_{d} {φ}_{1} ) - {V}_{pd} sin ( {w}_{d} {φ}_{1} ) \\ {V}_{Pc} cos ( {w}_{c} {φ}_{2} ) - {V}_{Pc} sin ( {w}_{c} {φ}_{2} ) {V}_{Pd} cos ( {w}_{d} {φ}_{2} ) - {V}_{pd} sin ( {w}_{d} {φ}_{2} ) \\ {V}_{Tc} sin ( {w}_{c} {φ}_{1} ) - {V}_{Tc} cos ( {w}_{c} {φ}_{1} ) {V}_{Td} sin ( {w}_{d} {φ}_{1} ) {V}_{Td} cos ( {w}_{d} {φ}_{1} ) \\ {V}_{Tc} sin ( {w}_{c} {φ}_{2} ) - {V}_{Tc} cos ( {w}_{c} {φ}_{2} ) {V}_{Td} sin ( {w}_{d} {φ}_{2} ) {V}_{Td} cos ( {w}_{d} {φ}_{2} )\end{matrix} ) ( \begin{matrix}{a}_{1} ( x ) \\ {a}_{2} ( x ) \\ {a}_{3} ( x ) \\ {a}_{4} ( x )\end{matrix} )$$

The procedure is then identical to that described above. Thus, the external field can be cancelled in similar manner by adding a third measurement on the component b_{P} and a third measurement on the component b_{T}.

It can be seen from the above description that the detector probes are characterized either by their locations in three-dimensional space by being mutually offset relative to the travel path of a moving body, or else by the component of the measured physical magnitude, such as for example the radial and axial components of the magnetic field.

1. A measurement sensor for determining the position of a moving body (11) moving along a determined path F, the sensor comprising a series of at least four detector probes (12₁, 12₂, 12₃, 12₄, . . . , 12_{N}) for detecting a physical magnitude coming from a target (13) securely mounted on the moving body, the target comprising at least one track (14) for creating a physical magnitude that is measurable by the detector probes and that varies along the path of the target with a function that is continuous and that includes a first harmonic (N_{c}) and a second harmonic (N_{d}), the probes being connected to a processor unit (16) for processing signals delivered by the probes, the processor unit including a reconstruction system (19) for performing a linear combination of the signals delivered by the detector probes and for obtaining from the liner combination of those signals at least firstly two quadrature signals (a₁, a₂) including solely the first harmonic, and secondly two quadrature signals (a₃, a₄) including solely the second harmonic, the unit also including a calculation system (20) for processing the quadrature signals in order to determine the position of the moving body.

2. A measurement sensor according to claim 1, characterized in that the calculation system (20) for determining the position of the moving body calculates the A tan 2 of the two quadrature signals including the first harmonic and the A tan 2 of the two quadrature signals including the second harmonic, the calculation system giving two relative positions for the moving body.

3. A measurement sensor according to claim 1, characterized in that the calculation system (20) calculates the difference between the two relative positions for the moving body modulo 2ϕ in order to obtain the absolute position (\hat{x}) of the moving body.

4. A measurement sensor according to claim 1, characterized in that the first harmonic and the second harmonic present respectively a first spatial frequency (N_{c}) and a second spatial frequency (N_{d}) such that the ratio of the spatial frequencies is given by the following relationship;
N_{d}=αN_{c}±1
where α is an integer greater than 1.

5. A measurement sensor according to claim 1, characterized in that the target (13) creates a magnetic field that varies continuously and that includes the first and second harmonics, the amplitude or the direction of the magnetic field being detected by the detector probes.

6. A measurement sensor according to claim 1, characterized in that the reconstruction system (19) performs a linear combination of the signals delivered by the probes by applying weighting weights, these weighting weights being programmable in such a manner as to enable the quadrature signals to be reconstructed for a spacing of given value between the probes.

7. A measurement sensor according to claim 1, characterized in that the weighting weights of the reconstruction system (19) are selected so as to obtain a zero contribution from the uniform component of the magnetic field to the reconstructed signals (a₁, a₂, a₃, a₄).

8. A measurement sensor according to claim 1, characterized in that the maximum distance between two of its detector probes (12₁, 12₂, 12₃, 12₄, . . . , 12_{N}) is strictly less than one half-period of the first spatial frequency (N_{c}).

9. A measurement sensor according to claim 1, characterized in that all of the detector probes (12₁, 12₂, 12₃, 12₄, . . . , 12_{N}) are grouped together in a single microelectronic integrated circuit.

10. A measurement sensor according to claim 1, characterized in that it includes at least two probes (12₁, 12₂) located on the path of the target that enable the component of the magnetic field that is tangential to the path to be measured, and at least two probes (12₃, 12₄) located along the path of the target that enable a component of the magnetic field that is perpendicular to the path to be measured.

11. A measurement sensor according to claim 1, characterized in that the target (13) has two tracks (14), each track being magnetized with one of the two harmonics, and in that the detector probes (12₁, 12₂, 12₃, 12₄, . . . , 12_{N}) are positioned substantially centered relative to the two tracks.
